(19) United States
(12) Patent Application Publication
(10) Pub. No.: US 2026/0141956 A1
(43) Pub. Date: May 21, 2026

(54) NON-VOLATILE MEMORY DEVICE

(71) Applicant: Samsung Electronics Co., Ltd., Suwon-si (KR)

(72) Inventors: Ik-Hyung Joo, Suwon-si (KR); Donggeun Lee, Suwon-si (KR); Myung Uk Park, Suwon-si (KR); Sukkang Sung, Suwon-si (KR); Cheon An Lee, Suwon-si (KR)

(21) Appl. No.: 19/302,721

(22) Filed: Aug. 18, 2025

(30) Foreign Application Priority Data
Nov. 18, 2024 (KR) 10-2024-0164055

(51) Int. Cl. G11C 16/14; G11C 16/08; G11C 16/30

(52) U.S. Cl. CPC G11C 16/14; G11C 16/08; G11C 16/30

(57) ABSTRACT

An example non-volatile memory device includes a memory cell array including a plurality of memory blocks, a voltage generator configured to generate an erase voltage provided to at least one of a bit line or a common source line connected to a selected block targeted by an erase operation among the plurality of memory blocks, and a first negative bias voltage provided to a gate induced drain leakage (GIDL) line connected to the selected block, and a control logic circuit configured to control the voltage generator, wherein the erase voltage is increased and maintained constant during an erase operation on the selected block, and wherein a GIDL voltage provided to the GIDL line connected to the selected block is maintained at the first negative bias voltage and increased in response to the erase voltage increasing.

### CROSS-REFERENCE TO RELATED APPLICATION

The present application claims priority to Korean Patent Application No. 10-2024-0164055, filed in the Korean Intellectual Property Office on Nov. 18, 2024, the entire contents of which are hereby incorporated by reference.

### BACKGROUND

Memory devices are used for storing data and grouped into a volatile memory device and a non-volatile memory device. A flash memory device as an example of a non-volatile memory device is used in mobile phones, digital cameras, portable computer devices, fixed computing devices, and other devices.

With the recent advancement of the multifunctionality of information communication devices, memory devices having a larger capacity and a higher integration are desired. For example, a three-dimensional (3D) non-volatile memory device is proposed including a plurality of word lines vertically stacked on a substrate.

### SUMMARY

The present disclosure relates to a non-volatile memory device, which can use an erase technique, such as a gate induced drain leakage (GIDL) erase technique. The GIDL erase technique may have hot carrier occurrence, and the injection of hot carrier into a charge storage layer may adversely affect the functions of the memory device such as changing the on-off characteristic of transistors. The present disclosure provides techniques to address these problems.

The problems to be solved are not limited the above, but the other tasks not mentioned above may be explicitly known to those skilled in the art from the description of the present disclosure below.

In some implementations, a non-volatile memory device includes a memory cell array including a plurality of memory blocks, a voltage generator configured to generate an erase voltage provided to at least one of a bit line or a common source line connected to a selected block targeted by an erase operation among the plurality of memory blocks, and a first negative bias voltage provided to a gate induced drain leakage (GIDL) line connected to the selected block; and a control logic circuit configured to control the voltage generator, wherein the erase voltage is increased and maintained constant during an erase operation on the selected block, and wherein a GIDL voltage provided to the GIDL line connected to the selected block is maintained at the first negative bias voltage and increased in response to the erase voltage increasing.

In some implementations, a non-volatile memory device includes a memory cell array including a plurality of memory blocks, a row decoder configured to apply an erase voltage to at least one of a bit line or a common source line connected to a selected block targeted by an erase operation among the plurality of memory blocks, and apply a GIDL voltage to a selected GIDL line connected to the selected block, a voltage generator configured to generate the erase voltage and a negative bias voltage, and a control logic circuit configured to control the row decoder and the voltage generator, wherein the control logic circuit is configured to, control the row decoder and the voltage generator to allow the erase voltage to be increased and maintained constant in response to an erase operation on the selected block being performed, and control the row decoder and the voltage generator to allow the GIDL voltage to be maintained at the negative bias voltage and increased in response to the erase voltage increasing.

In some implementations, a non-volatile memory device includes a memory cell array including a plurality of memory blocks, a voltage generator configured to generate an erase voltage provided to at least one of a bit line or a common source line connected to a selected block targeted by an erase operation among the plurality of memory blocks, and a negative bias voltage provided to a GIDL line connected to the selected block, and a control logic circuit configured to control the voltage generator, and in response to an erase operation on the selected block being performed, wherein the erase voltage is increased, and a GIDL voltage provided to GIDL line connected to the selected block is maintained at the negative bias voltage during a first time section, wherein the erase voltage and the GIDL voltage are increased during a second time section after the first time section, and wherein the erase voltage and the GIDL voltage are maintained constant during a third time section after the second time section.

In some implementations, holes may be rapidly formed by providing a constant negative bias voltage to a GIDL line at the initial stage of an erase operation compared to a comparative example. Therefore, the occurrence of the hot carrier may be reduced or prevented during the erase operation.

The effect that is obtained from the present disclosure is not limited to the above. The technical effect not mentioned above may be explicitly known to those skilled in the art from the description below.

### BRIEF DESCRIPTION OF THE DRAWINGS

FIG. 1 is a block view illustrated to explain an example of a data storage device.

FIG. 2 is a block view illustrated to explain an example of a memory device.

FIG. 3 is a circuit view illustrating an example of one of a plurality of memory blocks included in a memory cell array.

FIG. 4 is a vertical cross-sectional view illustrating an example of a string.

FIG. 5 is a view illustrating an example of an erase voltage, a GIDL voltage, and a word line voltage when an erase operation is performed.

FIG. 6 is an enlarged cross-sectional view illustrating an example of an area corresponding to area “A” of FIG. 4 among strings included in a selected block targeted by an erase operation.

FIG. 7 is a view illustrating an example of a channel potential of a selected block at the initial stage of an erase operation.

FIG. 8 is a view illustrating an example of an erase voltage during an erase operation.

FIG. 9 is an enlarged cross-sectional view illustrating an example of an area corresponding to area “A” of FIG. 4 of strings included in a non-selected block not targeted by an erase operation.

FIG. 10 is a view illustrated to explain an example of a memory device including pass transistors.

FIG. 11 and FIG. 12 are views illustrating examples of a selected GIDL pass transistor and a non-selected GIDL pass transistor.

FIG. 13 and FIG. 14 are views illustrating examples of a selected word line pass transistor and a non-selected word line pass transistor.

FIG. 15 is a block view illustrating an example of an SSD system to which a memory device is applied.

### DETAILED DESCRIPTION

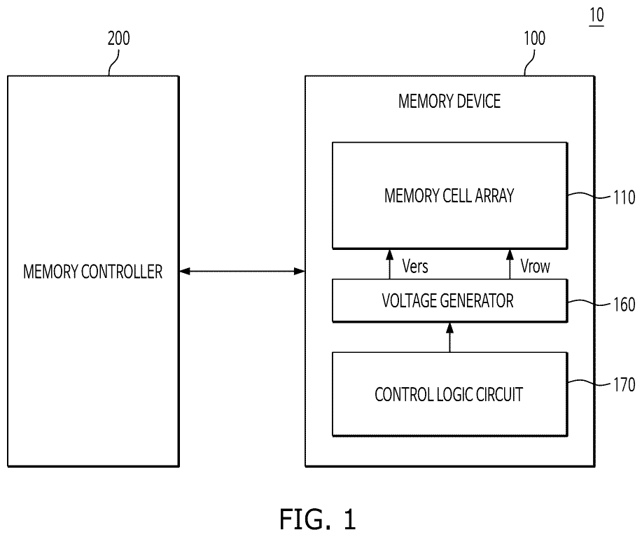

Referring to FIG. 1 to FIG. 15, implementations of the technical spirit of the present disclosure will be described in detail. Like reference numerals in the drawings denote like elements, and the redundant description will be omitted.

FIG. 1 is a block view illustrated to explain an example of a data storage device 10. Referring to FIG. 1, a data storage device 10 may include a memory device 100 and a memory controller 200, and the memory device 100 may include a memory cell array 110, a voltage generator 160, and a control logic circuit 170.

The memory device 100 may receive address signals, command signals, and user data from the memory controller 200. The memory device 100 may store user data based on the address signals and the command signals.

The memory device 100 may perform an erase operation on the stored data. The memory device 100 according to implementations may perform a gate induced drain leakage (GIDL) erase operation to which an erase voltage Vers is applied through common source lines and/or bit lines.

The memory cell array 110 may include a plurality of memory blocks that store data. For example, at least part of the plurality of memory blocks may store user data. Other parts of the plurality of memory blocks may include One Time Programmable Block (OTP block), Secure Block, etc. The erase operation may be performed on the memory block that stores user data. In some implementations, the erase operation may be performed in units of blocks. In some implementations, the block(s) targeted by the erase operation may be referred to as a ‘selected block’, and the block(s) not targeted by the erase operation may be referred to as a ‘non-selected block.’

The voltage generator 160 may generate an erase voltage Vers and row line voltages Vrow to be used during the erase operation. In some implementations, the erase voltage Vers may be provided to a common source line and/or a bit line during the erase operation. The low line voltages Vrow may be provided to row lines including word lines, dummy word lines, ground selection lines, string selection lines, GIDL lines, etc. during the erase operation. For example, the row line voltages Vrow may include a negative bias voltage provided to the GIDL line connected to the selected block, a word line voltage provided to the word line connected to the selected block, etc.

The control logic circuit 170 may control the memory cell array 110, the voltage generator 160, etc. For example, the control logic circuit 170 may control a voltage generator so that voltages to be provided to the common source lines, the bit line, the row lines, etc. may be appropriately generated during the erase operation.

The data storage device 10 may apply a constant negative bias voltage to the GIDL line at the initial stage of the erase operation to prevent the occurrence of the hot carriers due to the distortion of the channel gradient during the erase operation. The description thereof will be described in more detail below.

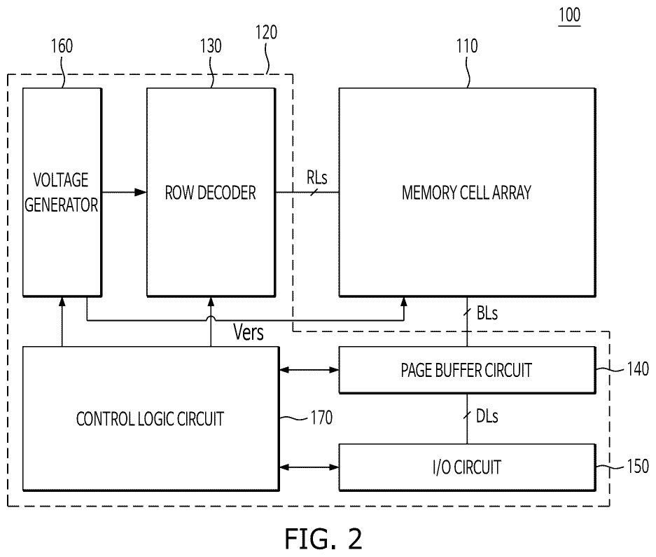

FIG. 2 is a block view illustrated to explain an example of a memory device 100. Referring to FIG. 2, a memory device 100 may include a memory cell array 110 and a peripheral circuit 120, and the peripheral circuit 120 may include a row decoder 130, a page buffer circuit 140, an input and output circuit 150, a voltage generator 160, and a control logic circuit 170.

The memory cell array 110 may include a plurality of memory blocks. The plurality of memory blocks each may have a two-dimensional (2D) structure or a three-dimensional (3D) structure. The memory cells may be formed in a direction parallel to a substrate in the memory block having a two-dimensional (2D) structure (or a horizontal structure). The memory cells may be formed in a direction perpendicular to a substrate in the memory block having a three-dimensional (3D) structure (or a vertical structure).

The row decoder 130 may be connected to the memory cell array 110 through row lines RLs. The row lines RLs may include string selection lines, ground selection lines, word lines, dummy word lines, GIDL lines, etc.

During the erase operation, the row decoder 130 may select a memory block to perform an erase operation from among a plurality of memory blocks under the control of the control logic circuit 170. During the erase operation, the row decoder 130, under the control of the control logic circuit 170, may apply the erase voltage Vers to at least one of bit lines BLs or the common source line connected to the selected block targeted by the erase operation, among a plurality of memory blocks of the selected block, and apply row line voltages (e.g., a GIDL voltage, a word line voltage, etc.) to the row lines RLs (e.g., GIDL lines, word lines, etc.) connected to the selected block. Additionally or alternatively, during the erase operation, the row decoder 130 may allow at least one of the row lines RLs to be floating under the control of the control logic circuit 170.

The page buffer circuit 140 may be connected to the memory cell array 110 through the bit lines BLs. The page buffer circuit 140 may temporarily store data to be programmed to a selected page, or data read from the selected page.

The input and output circuit 150 may be connected to the page buffer circuit 140 through data lines DLs internally, and may be externally connected to a memory controller (e.g., 200 in FIG. 1) through an input and output line.

The voltage generator 160 may generate various voltages required for operating the memory device 100. For example, the voltage generator 160, under the control of the control logic circuit 170, may generate various voltages provided to the row lines RLs, the bit lines BLs, etc., according to the operation of the memory device 100, such as a program voltage, a program verification voltage, a pass voltage, a read voltage, a read pass voltage, an erase voltage Vers, a word line voltage, a negative bias voltage, etc.

The control logic circuit 170 may control the overall operation of the memory device 100 in response to the commands or addresses provided from the memory controller (e.g., 200 of FIG. 1).

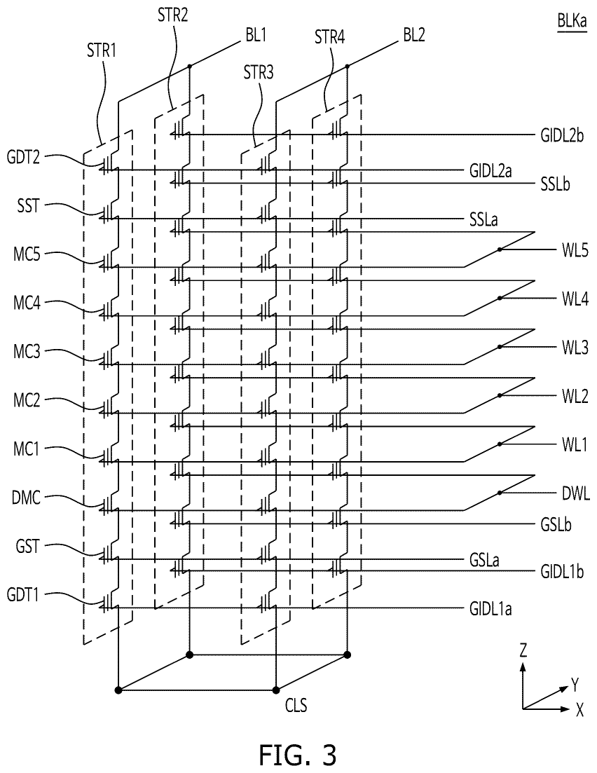

FIG. 3 is a circuit view illustrating an example of one memory block BLKa among a plurality of memory blocks included in the memory cell array 110. Referring to FIG. 3, one memory block BLKa is illustrated as including four (4) strings STR1 to STR4, but it is merely exemplary, but any number of strings may be included in one memory block BLKa.

Referring to FIG. 3, the memory block BLKa may include a plurality of strings STR1 to STR4 vertically (Z-axis direction) stacked on the substrate. Each of the plurality of strings STR1 to STR4 may be arranged in a first direction (X-axis direction) and a second direction (Y-axis direction).

The strings arranged in the same column among the plurality of strings STR1 to STR4 may be connected to the same bit line. For example, first and second strings STR1 and STR2 may be connected to a first bit line BL1, and third and fourth strings STR3 and STR4 may be connected to a second bit line BL2.

Each of the plurality of strings STR1 to STR4 may include a plurality of cell transistors. Each of the plurality of cell transistors may be a charge trap flash (CTF) memory cell, but the scope of the present disclosure is not limited thereto. The plurality of cell transistors may be stacked along a third direction (Z-axis direction).

The plurality of strings STR1 to STR4 may be jointly connected to a common source line CSL. For example, as illustrated in FIG. 3, the common source line CSL may be jointly connected to the bottoms of the plurality of strings STR1 to STR4. However, it is merely an example, but it is sufficient that the common source line CSL is electrically connected to the bottoms of the strings STR1 to STR4. The physical location of the common source line CSL is not limited to being at the bottoms of the strings STR1 to STR4.

For convenience of explanation, a first string STR1 will be used as a reference to explain the structure and arrangement of the strings. Each of the strings STR2, STR3, and STR4 may have a structure similar to that of the first string STR1, and the detailed description thereof will be omitted.

The plurality of cell transistors may be connected in series between a first bit line BL1 and the common source line CSL. For example, the plurality of cell transistors may include GIDL transistors GDT1 and GDT2, a string selection transistor SST, memory cells MC1 to MC5, a dummy memory cell DMC, and a ground selection transistor GST. In FIG. 3, one string STR1 is illustrated as including five (5) memory cells MC1 to MC5, but it is merely an example. One string STR1 may include any number of memory cells.

The GIDL transistors GDT1 and GDT2 may be placed at the bottom and/or top of the string STR1. For example, the string STR1 may include a first GIDL transistor GDT1 connected to the common source line CSL at the bottom of the string STR1. The gate of the first GIDL transistor GDT1 may be connected to a first GIDL line GIDL1a, and the first GIDL line GIDL1a may be placed adjacent to the common source line CSL. Additionally or alternatively, the string STR1 may include a second GIDL transistor GDT2 connected to the first bit line BL1 at the top of the string STR1. The gate of the second GIDL transistor GDT2 may be connected to a second GIDL line GIDL2a, and the second GIDL line GIDL2a may be placed adjacent to the bit lines BL1 and BL2. Although FIG. 3 illustrates that the string STR1 includes the first GIDL transistor GDT1 and the second GIDL transistor GDT2, this is merely exemplary. In some implementations, a GIDL transistor may be provided only at the top of the string STR1 or only at the bottom of the string STR1.

In some implementations, a string selection transistor SST may be provided between the memory cells MC1 to MC5 and the second GIDL transistor GDT2. The gate of the string selection transistor SST may be connected to a string selection line SSLa. Although one string selection transistor SST is illustrated in FIG. 3, this is merely exemplary. In some implementations, a plurality of string selection transistors connected in series may be provided between the memory cells MC1 to MC5 and the second GIDL transistor GDT2.

In some implementations, a ground selection transistor GST may be provided between the dummy memory cell DMC and the first GIDL transistor GDT1. The gate of the ground selection transistor GST may be connected to a ground selection line GSLa. Although one ground selection transistor GST is illustrated in FIG. 3, it is only exemplary. In some implementations, a plurality of ground selection transistors connected in series may be provided between the dummy memory cell DMC and the first GIDL transistor GDT1.

The memory cells MC1 to MC5 may be connected in series between the string selection transistor SST and the dummy memory cell DMC. The gates of the memory cells MC1 to MC5 may be respectively connected to word lines WL1 to WL5.

In some implementations, the dummy memory cell DMC may be provided between the memory cells MC1 to MC5 and the first GIDL transistor GDT1. The gate of the dummy memory cell DMC may be connected to the dummy word line DWL. Although one dummy memory cell DMC is illustrated in FIG. 3, but it is exemplary. In some implementations, a plurality of dummy memory cells connected in series may be provided between the memory cells MC1 to MC5 and the first GIDL transistor GDT1. Additionally or alternatively, one or more dummy memory cells may be provided between the string selection transistor SST and the memory cells MC1 to MC5.

During the erase operation, the first GIDL transistor GDT1 and/or the second GIDL transistor GDT2 may operate as a transistor for hole generation. For example, when an erase voltage is provided to the drain of the second GIDL line GIDL2a through the first bit line BL1 and/or an erase voltage is provided to the drain of the first GIDL line GIDL1a through the common source line CSL, a high electric field may be generated in a channel region adjacent to the second GIDL transistor GDT2 and/or a channel region adjacent to the first GIDL transistor GDT1 due to the channel potential difference caused by an erase voltage. Due to the high electric field, holes may be generated in the channel region adjacent to the second GIDL transistor GDT2 and/or the first GIDL transistor GDT1.

The holes generated in the channel region adjacent to the first GIDL transistor GDT1 and/or the holes generated in the channel region adjacent to the second GIDL transistor GDT2 may be injected into the channel of the string STR1. Accordingly, a relatively large potential difference may be formed between the channel regions instantaneously, which may cause the hot carrier. A memory device may apply a constant negative bias voltage to the GIDL line (GIDL1a and/or GIDL2a) at the initial stage of the erase operation to prevent the occurrence of the hot carriers. The holes may be formed rapidly at the initial stage of the erase operation, which prevents the occurrence of the hot carrier by reducing the distortion of the channel gradient.

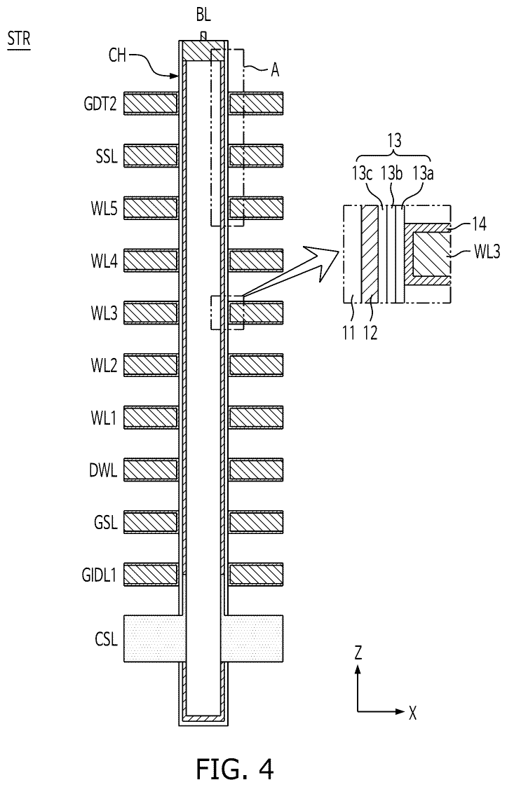

FIG. 4 is a vertical cross-sectional view illustrating an example of a string STR. Referring to FIG. 4, the string STR may include a channel structure CH, and a plurality of row lines may be alternately stacked adjacent to the channel structure CH.

The channel structure CH may include a vertical channel layer 12, a buried insulating layer 11 that fills the inside of the vertical channel layer 12, and a vertical insulating layer 13 disposed between the vertical channel layer 12 and row lines. In some implementations, the channel structure CH may have an inclined side surface with a diameter narrowing toward the substrate. Alternatively, the channel structure CH may have an inclined side surface with a diameter widening toward the substrate. In some implementations, the string STR may include two or more channel structures CHs stacked vertically.

The vertical channel layer 12 may include a semiconductor material such as polysilicon or single crystal silicon. The semiconductor material may be, for example, a material that is not doped with impurities. In some implementations, the vertical channel layer 12 may have a columnar shape such as a cylinder or a prism without the buried insulating layer 11. The vertical insulating layer 13 may include a blocking film 13a, a charge storage film 13b, and a tunnel insulating film 13c.

The blocking film 13A may be disposed between the charge storage film 13B and row lines. At least part of the blocking film 13A may be formed to surround the row lines and provided as a blocking layer 14. The blocking film 13A may include a material having a greater energy band gap than the charge storage film 13B. For example, the blocking film 13A may include a silicon oxide film, a silicon nitride film, and/or a silicon oxynitride film.

The charge storage film 13B may be interposed between the blocking film 13A and the tunnel insulating film 13C. For example, the charge storage film 13B may include at least one of a silicon nitride film, a silicon oxide nitride film, a Si-rich nitride film, nanocrystalline Si, or a laminated trap layer.

The tunnel insulating film 13C may be disposed between the charge storage film 13B and the vertical channel layer 12. The tunnel insulating film 13C may include a material having a band gap greater than the charge storage film 13B. For example, the tunnel insulating film 13C may include a silicon oxide layer.

The plurality of row lines may be alternately stacked on the common source line CSL. The plurality of row lines may include, for example, the first GIDL line GIDL1a, the ground selection line GSLa, the dummy word line DWL, the word lines WL1 to WL5, the string selection line SSLa, and the second GIDL line GIDL2a. The plurality of row lines may include, for example, a metal and/or a conductive metal nitride such as polysilicon (Poly-Si) or tungsten (W). In FIG. 4, the word lines WL1 to WL5 are illustrated, but it is only for the convenience of explanation, and any number of word lines may be stacked adjacent to the channel structure CH.

The bit line BL may be placed at the top of the string STR, and the common source line CSL may be placed at the bottom of the string STR. For example, the common source line CSL may be an impurity region formed in or on the substrate. During the erase operation, the erase voltage may be provided to the string STR through the bit line BL. Additionally or alternatively, during the erase operation, the erase voltage may be provided to the string STR through the common source line CSL.

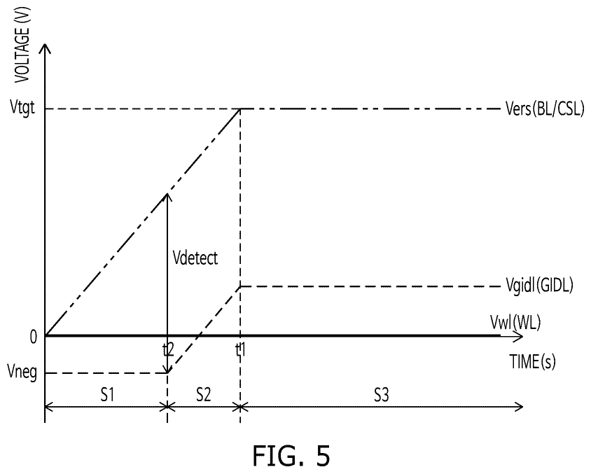

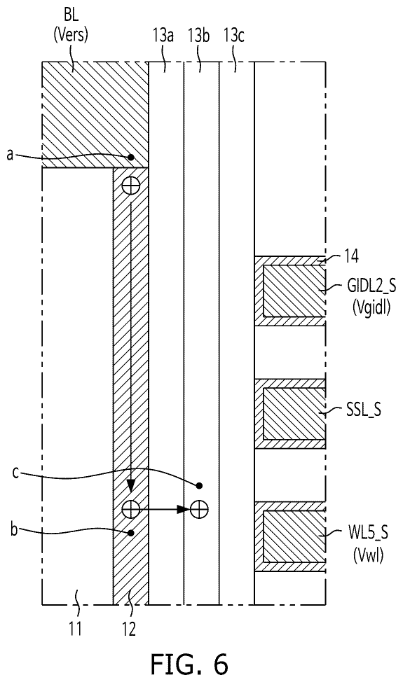

FIG. 5 is a diagram illustrating examples of an erase voltage Vers, a GIDL voltage Vgidl, and a word line voltage Vwl during the erase operation, and FIG. 6 is an enlarged cross-sectional view illustrating an example of an area corresponding to area “A” of FIG. 4 among strings included in a selected block that is a target of the erase operation. The erase voltage Vers may indicate a voltage applied to the bit line BL and/or the common source line CSL during the erase operation, the GIDL voltage Vgidl may indicate a voltage applied to a GIDL line (referred to as a selected GIDL line) GIDL2_S connected to a selected block during the erase operation, and the word line voltage Vwl may indicate a voltage applied to a word line (referred to as a selected word line) WL5_S connected to a selected block. For convenience of explanation, it is assumed that the erase voltage Vers may be provided through the bit line BL during the erase operation and that holes (+) formed in a channel region at the top of the string may be injected into the channel.

Referring to FIG. 5, the erase voltage Vers may increase and be maintained constant during the erase operation. A control logic circuit (e.g., 170 of FIG. 1 and FIG. 2) may control a row decoder (e.g., 130 of FIG. 1 and FIG. 2) and a voltage generator (e.g., 160 of FIG. 1 and FIG. 2) so that the erase voltage Vers may be increased and maintained constant. The term ‘maintained constant’ may indicate that a voltage is maintained at a specific voltage level, but also that a voltage may be maintained within a tolerance range around a specific voltage level (e.g., around ±0.5V).

The erase voltage Vers may be increased during a period ranging from an initial point 0(s) of the erase operation to a first point t1(s) (e.g., a first time section S1 and a second time section S2), and maintained constant from the first point t1(s) to an end point of the erase operation (e.g., during a third time section S3). In some implementations, the first time point t1(s) at which the erase voltage Vers starts being maintained may be the time point (or around the time point) at which the erase voltage Vers reaches a predetermined target voltage level Vtgt. After being increased, the erase voltage Vers may be maintained constant at the predetermined target voltage level Vtgt in response to reaching the predetermined target voltage level Vtgt.

During a time when the erase voltage Vers increases, the GIDL voltage Vgidl applied to a selected GIDL line GIDL2_S may be maintained at a negative bias voltage Vneg (e.g., −3 V) and then increased. The control logic circuit (e.g., 170 of FIGS. 1 and 2) may control the row decoder (e.g., 130 of FIGS. 1 and 2) and the voltage generator (e.g., 160 of FIGS. 1 and 2) so that the GIDL voltage Vgidl is maintained at the negative bias voltage Vneg and then increased during a time when the erase voltage Vers increases. For example, the control logic circuit may control the row decoder and voltage generator so that the selected GIDL line GIDL2_S may be electrically floating after the GIDL voltage Vgidl is maintained at the negative bias voltage Vneg.

The GIDL voltage Vgidl may be maintained at the negative bias voltage Vneg from a start time 0(s) of the erase operation to a second time point t2(s) (i.e., during a first time section S1), and then increased from the second time point t2(s) to a first time point t1(s) (i.e., during a second time section S2). The second time point t2(s) at which the GIDL voltage Vgidl starts to increase may be a time point at which the selected GIDL line GIDL2_S becomes electrically floating. In addition, the GIDL voltage Vgidl may be maintained constant from the first time point t1(s) to an end point of the erase operation (i.e., during a third time section S3).

During the first time section S1 in which the erase voltage Vers is increased and the GIDL voltage Vgidl is maintained constant at the negative bias voltage Vneg, the difference between the erase voltage Vers and the GIDL voltage Vgidl may increase. During the second time section S2 in which the erase voltage Vers and the GIDL voltage Vgidl increase, the difference between the erase voltage Vers and the GIDL voltage Vgidl may remain constant. During the second time section S2 in which the erase voltage Vers and the GIDL voltage Vgidl increase, the erase voltage Vers and the GIDL voltage Vgidl may increase at the same rate of increase. Increasing at the same increase rate may indicate increasing at an increase rate within a predetermined margin of error. During the third time section S3 in which the erase voltage Vers and the GIDL voltage Vgidl are maintained constant, the difference between the erase voltage Vers and the GIDL voltage Vgidl may be maintained constant. The difference between the erase voltage Vers and the GIDL voltage Vgidl may increase from the start time 0(s) of the erase operation to the second time point t2(s) (i.e., during the first time section S1), and may be maintained constant from the first time point t1(s) to the end point of the erase operation (i.e., during the second time section S2 and the third time section S3).

In some implementations, the second time point t2 at which the GIDL voltage Vgidl begins to increase and the difference between the erase voltage Vers and the GIDL voltage Vgidl begins to remain constant may be the time point (or around the time point) at which the difference between the erase voltage Vers and the GIDL voltage Vgidl reaches a predetermined detection voltage level Vdetect. The GIDL voltage Vgidl may increase in response to the difference between the erase voltage Vers and the GIDL voltage Vgidl reaching the predetermined detection voltage level Vdetect after being maintained at the negative bias voltage Vneg. Additionally, the difference between the erase voltage Vers and the GIDL voltage Vgidl may be increased and maintained constant at the predetermined detection voltage level Vdetect in response to the difference between the erase voltage Vers and the GIDL voltage Vgidl reaching the predetermined detection voltage level Vdetect.

During the erase operation, the word line voltage Vwl applied to the selected word line WL5_S may be maintained at a ground voltage (0V) or a positive voltage close to the ground voltage (e.g., 0.3V).

Referring to FIG. 6, during the erase operation, a potential difference may occur between the selected GIDL line GIDL2_S and the bit line BL due to a difference between the GIDL voltage Vgidl and the erase voltage Vers. Due to the potential difference generated between the selected GIDL line GIDL2_S and the bit line BL, a band-to-band tunneling effect may occur in a junction region a of the vertical channel layer 12 and the bit line BL.

The electrons of the vertical channel layer 12 may move to the junction region (a) due to the band-to-band tunneling effect, and holes (+) may be generated where the electrons are present. An isolated region may be generated in a part of the vertical channel layer 12 adjacent to the selected GIDL line GIDL2_S, and the holes (+) may be accumulated in the isolated region. As the potential difference generated between the selected GIDL line GIDL2_S and the bit line BL increases, the amount of generated holes (+) and the amount of holes (+) accumulated in the isolated region may increase.

During the erase operation, the word line voltage Vwl (e.g., a ground voltage (0V) or a positive voltage (0.3V) close to the ground voltage) may be applied to a selected word line WL5_S, and a selected string selection transistor SST_S may be turned off. Accordingly, the vertical channel layer 12 may be electrically floating, and the word line voltage Vwl may be coupled to the vertical channel layer 12 with the insulating layers 13a to 13c interposed therebetween. Due to the coupling effect, the same voltage (e.g., 0V or 0.3V) as the word line voltage Vwl may be applied to the vertical channel layer b adjacent to the selected word line WL5_S. Accordingly, a potential difference may occur between the junction region a and the vertical channel layer b adjacent to the selected word line WL5_S, and the holes (+) accumulated in the isolated region may move in the direction of the selected word line WL5_S along the vertical channel layer 12.

Accordingly, the potential difference may occur between the vertical channel layer b adjacent to the selected word line WL5_S and the charge storage film 13B, and the holes (+) of the vertical channel layer b adjacent to the selected word line WL5_S may move to the charge storage film 13b adjacent to the selected word line WL5_S.

During the erase operation, the holes (+) generated at the top of the string may be injected into the vertical channel layer 12, and the holes (+) injected into the vertical channel layer 12 may move to the charge storage film 13B. Accordingly, data stored in the memory cell of the selected block may be erased.

During the erase operation, distortion of the channel gradient of the string may occur. The distortion of the channel gradient may refer to a change in the electric field formed by the voltage difference across the channel. The distortion of the channel gradient may cause the hot carriers. When the holes (+) fail to rapidly move from the top of the string to the bottom of the string, distortion of the channel gradient may occur, leading to the generation hot carriers at the bottom of the string, which may adversely affect the function of the memory device. The memory device may provide the constant negative bias voltage Vneg to the GIDL line GIDL2_S at the initial stage of the erase operation. Compared to the case where a ground voltage or a positive voltage is provided to the GIDL line GIDL2_S at the initial stage of the erase operation, the holes (+) may be rapidly generated due to the large potential difference between the GIDL line GIDL2_S and the bit line BL compared to an implementation where a ground voltage or a positive voltage is applied to the GIDL line GIDL2_S at the initial stage of the erase operation. Accordingly, the occurrence of the hot carriers may be reduced or prevented.

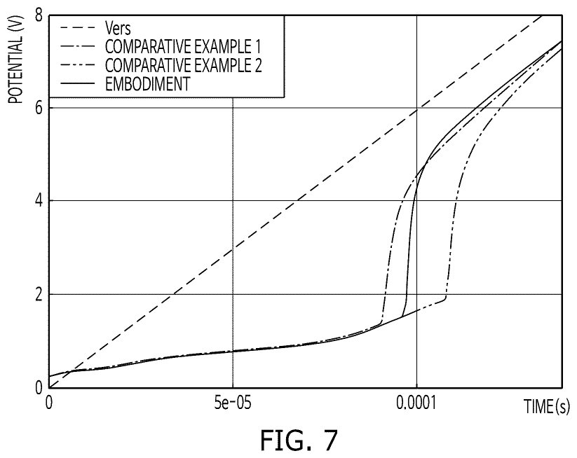

FIG. 7 is a view illustrating an example of a channel potential of a selected block at the initial stage of the erase operation. Referring to FIG. 7, comparative example 1 illustrates an example of a channel potential of a selected block at the initial stage of the erase operation in the memory device according to a comparative example having a first layer count (e.g., 225 layers), and comparative example 2 illustrates an example of a channel potential of a selected block at the initial stage of the erase operation in the memory device according to a comparative example having a second layer count (e.g., 513 layers) greater than the first layer count. At the initial stage of the erase operation, as the erase voltage increases, the holes may be generated, accumulated, and moved due to the potential difference between the erase voltage and the GIDL voltage. Therefore, the channel potential may rapidly increase. As the layer count of the memory device increases, the length of the channel may also increase. Therefore, as the layer count of the memory device increases, a time point at which the channel potential increases sharply during the erase operation may become slower. Accordingly, it was identified that a time point at which the channel potential increases rapidly is slower in comparative example 2 having a greater layer count than comparative example 1.

FIG. 7 illustrates an example of a channel potential of a selected block at the initial stage of the erase operation in the memory device having a second layer count (the same as layer count in comparative example 2). The memory device may provide a constant negative bias voltage to the GIDL line at the initial stage of the erase operation, and a ground voltage or a positive voltage may be provided to the GIDL line at the initial stage of the erase operation. Compared to comparative example 2 having the same layer count, holes (+) may be more rapidly generated and accumulated, so that a time point at which the channel potential increases rapidly may become faster, and it is identified that the potential increase pattern was similar to that of comparative example 1 with a lower layer count.

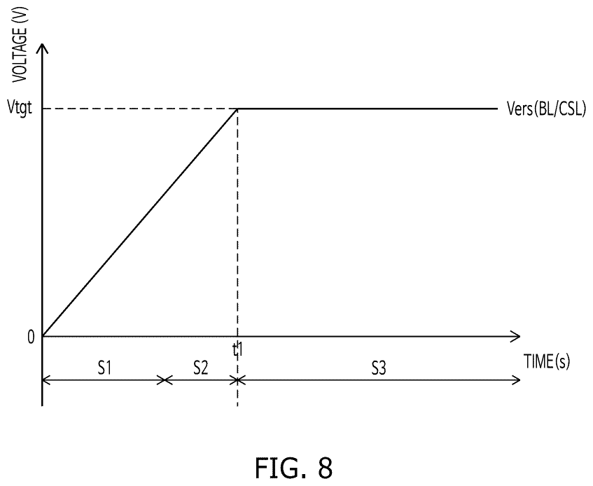

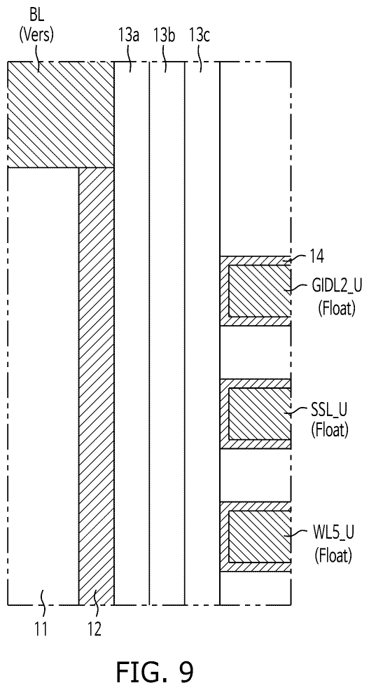

FIG. 8 is a view illustrating an example of an erase voltage Vers during the erase operation, FIG. 9 is an enlarged cross-sectional view illustrating an example of an area corresponding to area “A” of FIG. 4 of the string included in a non-selected block that is not targeted by the erase operation. The erase voltage Vers may be a voltage applied to the bit line BL and/or the common source line CSL during the erase operation.

Referring to FIG. 8, during the erase operation, the erase voltage Vers may be increased and maintained constant. The control logic circuit (e.g., 170 of FIG. 1 and FIG. 2) may control the row decoder (e.g., 130 of FIG. 1 and FIG. 2) and the voltage generator (e.g., 160 of FIG. 1 and FIG. 2) so that the erase voltage Vers may be increased and maintained constant.

The erase voltage Vers may be increased from the start time 0(s) of the erase operation to the first time point t1(s) (i.e., during the first time section S1 and the second time section S2), and maintained constant from the first time point t1(s) to the end point of the erase operation (i.e., during the third time section S3). In some implementations, the first time point t1 at which the erase voltage Vers begins to be maintained may be the time point (or around the time point) at which the erase voltage Vers reaches a predetermined target voltage level Vtgt. The erase voltage Vers may be increased and maintained constant at the predetermined target voltage level Vtgt in response to the erase voltage Vers reaching the predetermined target voltage level Vtgt.

Referring to FIG. 9, during the erase operation, the row lines (e.g., non-selected GIDL line GIDL2_U, non-selected word line WL5_U, etc.) connected to the non-selected block not targeted by the erase operation, may become electrically floating. During the erase operation, the control logic circuit (e.g., 170 of FIG. 1 and FIG. 2) may control the row decoder (e.g., 130 of FIG. 1 and FIG. 2) and the voltage generator (e.g., 160 of FIG. 1 and FIG. 2) so that the non-selected row lines not targeted by the erase operation may become electrically floating.

Due to the coupling effect, the same voltage as the erase voltage Vers may be applied to the bit line BL (and/or the common source line CSL), the vertical channel layer 12, the non-selected row lines (e.g., GIDL2_U, WL5_U, etc). Accordingly, unlike the selected block, the holes (+) may fail to be generated in the channel layer of the non-selected block. Consequently, data stored in the memory cell of the non-selected block may be maintained without being erased.

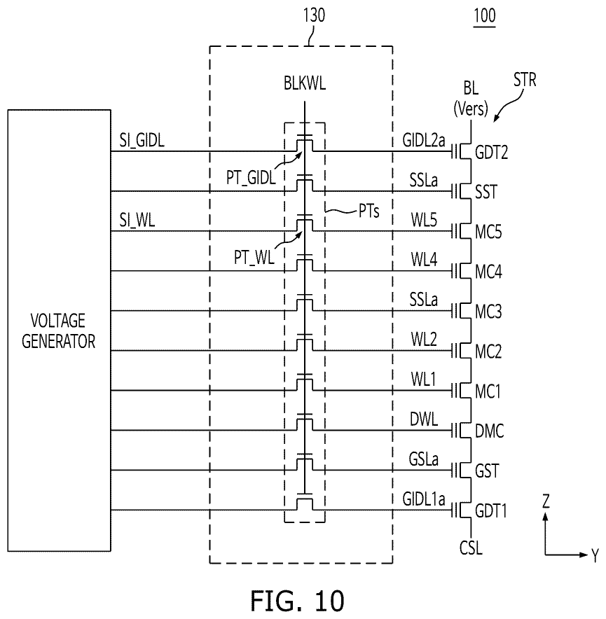

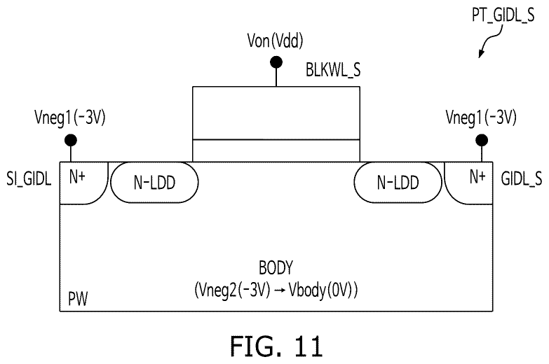

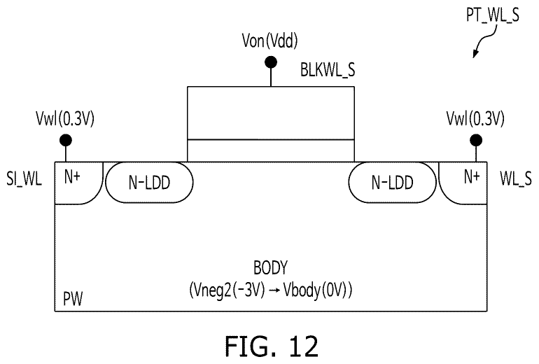

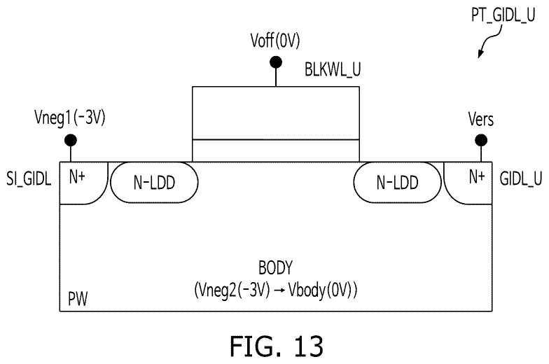

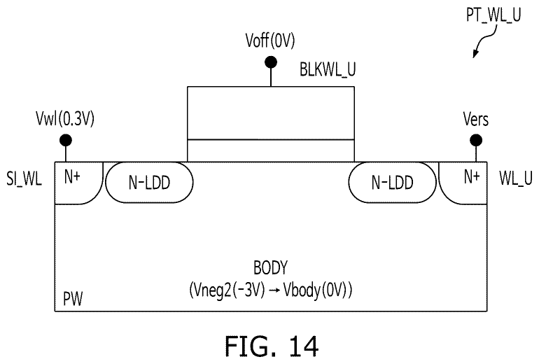

FIG. 10 is a view illustrating an example of a memory device 100 including pass transistors PTs, FIGS. 11 and 12 are views illustrating examples of a selected GIDL pass transistor PT_GIDL_S and a non-selected GIDL pass transistor PT_GIDL_U, respectively, and FIGS. 13 and 14 are views illustrating examples of a selected word line pass transistor PT_WL_S and a non-selected word line pass transistor PT_WL_U, respectively.

Referring to FIG. 10, the memory device 100 may include a row decoder 130 interposed between a voltage generator 160 and a memory cell array (e.g., a string STR). The row decoder 130 may or may not provide voltages (e.g., a word line voltage, a negative bias voltage, etc.) generated by the voltage generator to the row lines (GIDL lines GIDL1a and GIDL2a, a string selection line SSL, word lines WL1 to WL5, a dummy word line DWL, and a ground selection line GSL, etc.).

In some implementations, the row decoder 130 may include pass transistors PTs. Gates of the pass transistors PTs may be connected to block word lines BLKWL. Sources (or drains) of the pass transistors PTs may be connected to source input lines (e.g., a GIDL source input line SI_GIDL, a word line source input line SI_WL, etc.) connected to the voltage generator 160, and drains (or sources) of the pass transistors PTs may be connected to the row lines. Voltages generated by the voltage generator may pass through the pass transistors PTs to be provided to the row lines, or may be blocked by the pass transistors PTs not to be provided to the row lines.

The pass transistors PTs may include a GIDL pass transistor PT_GIDL and a word line pass transistor PT_WL.

During the erase operation, a first negative bias voltage Vneg1 (e.g., −3 V) provided through the GIDL source input line SI_GIDL may or may not be provided to the GIDL lines GIDL1a and GIDL2a through the GIDL pass transistor PT_GIDL.

For example, referring to FIG. 11, a selected GIDL pass transistor PT_GIDL_S connected to a selected GIDL line GIDL_S of a selected block targeted by the erase operation may be turned on by applying a turn-on voltage Von (e.g., an operating voltage Vdd) to a selected block word line BLKWL_S. Accordingly, the first negative bias voltage Vneg1 provided through the GIDL source input line SI_GIDL may be provided to the selected GIDL line GIDL_S through the selected GIDL pass transistor PT_GIDL_S. In response to the potential difference between the bit line BL and the selected GIDL line GIDL_S reaching a predetermined detection voltage level, the selected GIDL line GIDL_S may be electrically floating. For example, the selected GIDL line GIDL_S may be electrically floating by applying the same voltage as the gate of the selected GIDL pass transistor PT_GIDL_S (the selected block word line BLKWL_S) to the source of the selected GIDL pass transistor PT_GIDL_S (the GIDL source input line SI_GIDL).

Referring to FIG. 12, a non-selected GIDL pass transistor PT_GIDL_U connected to a non-selected GIDL line GIDL_U of the non-selected block not targeted by the erase operation may be turned off by applying a turn-off voltage Voff (e.g., 0 V) to the non-selected block word line BLKWL_U. The first negative bias voltage Vneg1 provided through the GIDL source input line SI_GIDL may be blocked by the non-selected GIDL pass transistor PT_GIDL_U not to be provided to the non-selected GIDL line GIDL_U. The non-selected GIDL line GIDL_U may be electrically floating, and the voltage same as the erase voltage Vers may be applied to the non-selected GIDL line GIDL_U due to the coupling effect.

During the erase operation, the word line voltage Vwl (e.g., 0.3 V) provided through the word line source input line SI_WL may or may not be provided to the word line through the word line pass transistor PT_WL.

For example, referring to FIG. 13, a selected word line pass transistor PT_WL_S connected to the selected word line WL_S of the selected block targeted by the erase operation may be turned on by applying a turn-on voltage Von (e.g., an operating voltage Vdd) to the selected block word line BLKWL_S. Accordingly, the word line voltage Vwl provided through the word line source input line SI_WL may be provided to the selected word line WL_S through the selected word line pass transistor PT_WL_S.

Referring to FIG. 14, a non-selected word line pass transistor PT_WL_U connected to a non-selected word line WL_U of a non-selected block not targeted by the erase operation may be turned off by applying a turn-off voltage Voff (e.g., 0 V) to the non-selected block word line BLKWL_U. Accordingly, the word line voltage Vwl provided through the word line source input line SI_WL may be blocked by the non-selected word line pass transistor PT_WL_U not to be provided to the non-selected word line WL_U. The non-selected word line WL_U may be electrically floating, and a voltage same as the erase voltage Vers may be applied to the non-selected word line WL_U due to the coupling effect.

Referring to FIGS. 10 to 14, pass transistors PTs including a selected GIDL pass transistor PT_GIDL_S, a non-selected GIDL pass transistor PT_GIDL_U, a selected word line pass transistor PT_WL_S, and a non-selected word line pass transistor PT_WL_U may share the same body BODY.

In some implementations, during a time when the first negative bias voltage Vneg1 is provided to the selected GIDL line GIDL_S, a body voltage Vbody provided to the body BODY of the pass transistors PTs may be maintained at a second negative bias voltage Vneg2 (e.g., −3 V). The level of the second negative bias voltage Vneg2 may be the same as or different from the level of the first negative bias voltage Vneg1 provided to the selected GIDL line GIDL_S.

In some implementations, in response to the GIDL voltage applied to a selected GIDL line GIDL_S switching from a negative voltage to a positive voltage, the body voltage Vbody provided to the body BODY of pass transistors PTs may switch from a negative voltage to a ground voltage (e.g., 0 V or around the positive voltage).

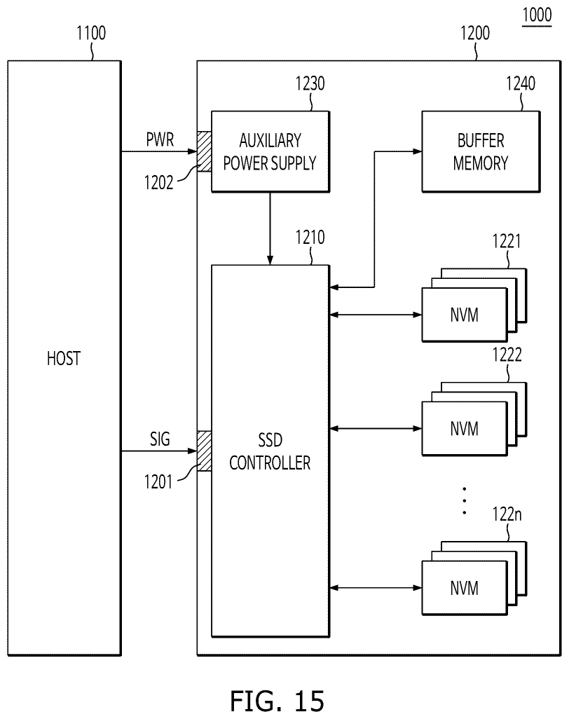

FIG. 15 is a block view illustrating an example of an SSD system 1000 to which a memory device is applied. In some implementations, the SSD system 1000 may be provided in tens of host machines that perform hundreds of virtual machines, or a data center including servers. For example, the SSD system 1000 may be a computing device such as a laptop computer, a desktop computer, a server computer, a workstation, a portable communication terminal, a PDA (Personal Digital Assistant), a PMP (Portable Multimedia Player), a smartphone, a tablet PC, a virtual machine, or a virtual computing device thereof. Alternatively, the SSD system 1000 may be a part of components included in a computing system such as a graphics card. The SSD system 1000 is not limited to the hardware configuration described below, and other configurations are also possible.

Referring to FIG. 15, the SSD system 1000 may include a host 1100 and an SSD 1200.

The host 1100 may refer to a data processing device capable of processing data. The host 1100 may execute an operating system (OS) and/or various applications. The host 1110 may include a Central Processing Unit (CPU), a Graphics Processing Unit (GPU), a Neural Processing Unit (NPU), a Digital Signal Processor (DSP), a microprocessor, or an Application Processor (AP). In some implementations, the SSD system 1000 may be included in a mobile device, and the host 1100 may be implemented as an Application Processor (AP). In some implementations, the host 1100 may be implemented as a System-On-a-Chip (SoC), and thus may be built into the SSD system 1000. The host 1100 may include one or more processors. According to some implementations, the host 1100 may include a multi-core processor.

The host 1100 may execute executable commands by one or more machines, software, firmware, or pieces of a combination thereof. The host 1100 may control the data process operation for the SSD 1200. For example, the host 1100 may control a read operation, a program operation, an erase operation, and a compensation operation for the erase cells, etc. of the data of SSD 1200.

The host 1100 may communicate with the SSD 1200 using various protocols. For example, the host 1100 may communicate with the SSD 1200 using an interface protocol such as Peripheral Component Interconnect-Express (PCI-E), Advanced Technology Attachment (ATA), Serial ATA (SATA), Parallel ATA (PATA), or serial attached SCSI (SAS). In addition, various other interface protocols such as Universal Flash Storage (UFS), Universal Serial Bus (USB), Multi-Media Card (MMC), Enhanced Small Disk Interface (ESDI), or Integrated Drive Electronics (IDE) may be applied to the protocol between the host 1100 and the SSD 1200.

The SSD 1200 may exchange signals with the host 1100 through a signal connector, and receive power through a power connector. The SSD 1200 may include an SSD controller 1210, an auxiliary power supply device 1230, and memory devices 1221, 1222, . . . , and 122n. In some implementations, the memory devices 1221, 1222, . . . , and 122n may be vertically stacked NAND flash memory devices. The memory devices 1221, 1222, . . . , and 122n may be implemented using the implementations described above with reference to FIGS. 1 to 14, and the memory devices 1221, 1222, . . . , and 122n may perform an erase operation according to the implementations of the present disclosure. The memory devices 1221, 1222, . . . , and 122n may prevent the occurrence of the hot carrier due to distortion of the channel gradient during the erase operation by applying a constant negative bias voltage to a GIDL line at the initial stage of the erase operation.

While this specification contains many specific implementation details, these should not be construed as limitations on the scope of any invention or on the scope of what may be claimed, but rather as descriptions of features that may be specific to particular implementations of particular inventions. Certain features that are described in this specification in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

While the present disclosure has been described with reference to some implementations and drawings, and implementations have been described using specific terms through the specification. It is only for the purpose of explaining the technical spirit of the present disclosure, but is not used to limit the scope of the present disclosure described in the claims. It will be apparent to those skilled in the art that various modifications and changes may be made within the scope of the appended claims and their equivalents. Therefore, the technical protection scope of the present disclosure should be determined by the technical spirit of the appended claims.

What is claimed is:

1. A non-volatile memory device comprising:
a memory cell array comprising a plurality of memory blocks;
a voltage generator configured to
generate an erase voltage, the erase voltage being provided to at least one of a bit line or a common source line connected with a block among the plurality of memory blocks, the block being targeted for an erase operation, and
generate a first negative bias voltage, the first negative bias voltage being provided to a gate induced drain leakage (GIDL) line connected with the block; and
a control logic circuit configured to control the voltage generator,
wherein, during the erase operation, the erase voltage is configured to increase to a first voltage level and then remain at the first voltage level on the block, and
wherein, based on the erase voltage increasing to the first voltage level, a GIDL voltage provided to the GIDL line connected with the block is configured to remain at the first negative bias voltage and then increase to a second voltage level.

2. The non-volatile memory device of claim 1, wherein the GIDL voltage is configured to increase based on a difference between the erase voltage and the GIDL voltage being at a predetermined detect voltage level.

3. The non-volatile memory device of claim 1, wherein, during the erase operation, a difference between the erase voltage and the GIDL voltage is configured to increase to a third voltage level and then remain at the third voltage level.

4. The non-volatile memory device of claim 3, wherein the third voltage level is a predetermined detect voltage level.

5. The non-volatile memory device of claim 1, wherein an increase rate of the erase voltage is a same as an increase rate of the GIDL voltage.

6. The non-volatile memory device of claim 1, wherein the first voltage level is a predetermined target voltage level.

7. The non-volatile memory device of claim 1, wherein the GIDL voltage is configured to remain at the second voltage level based on the erase voltage remaining at the first voltage level.

8. The non-volatile memory device of claim 1, wherein the voltage generator is configured to generate a word line voltage and provide the word line voltage to a word line connected with the block, and
wherein the word line voltage is configured to remain at a ground voltage or a positive voltage based on the erase operation being performed on the block.

9. The non-volatile memory device of claim 1, comprising:
a row decoder interposed between the voltage generator and the memory cell array, the row decoder comprising a plurality of pass transistors,
wherein the first negative bias voltage is provided to the GIDL line through the plurality of pass transistors, and
wherein a body voltage provided to a plurality of bodies of the plurality of pass transistors is configured to remain at a second negative bias voltage based on the GIDL voltage provided to the GIDL line remaining at the first negative bias voltage.

10. The non-volatile memory device of claim 9, wherein the first negative bias voltage and the second negative bias voltage are at a same level.

11. The non-volatile memory device of claim 9, wherein the body voltage is configured to be converted from a negative voltage to a ground voltage or a positive voltage based on the GIDL voltage provided to the GIDL line being converted from a negative voltage to a positive voltage.

12. The non-volatile memory device of claim 1, wherein the GIDL line is adjacent to the bit line, and
wherein the erase voltage is provided to the bit line.

13. The non-volatile memory device of claim 1, wherein the GIDL line is adjacent to the common source line, and
wherein the erase voltage is provided to the common source line.

14. The non-volatile memory device of claim 1, wherein the GIDL line comprises a first GIDL line adjacent to the common source line and a second GIDL line adjacent to the bit line, and
wherein the erase voltage is provided to the common source line and the bit line.

15. A non-volatile memory device comprising:
a memory cell array comprising a plurality of memory blocks;
a row decoder configured to
apply an erase voltage to at least one of a bit line or a common source line connected with a block among the plurality of memory blocks, the block being targeted for an erase operation, and
apply a gate induced drain leakage (GIDL) voltage to a GIDL line connected with the block;
a voltage generator configured to generate the erase voltage and a negative bias voltage; and
a control logic circuit configured to
control, based on the erase operation on the block being performed, the row decoder and the voltage generator to control the erase voltage to increase to a first voltage level and then remain at the first voltage level, and
control, based on the erase voltage increasing to the first voltage level, the row decoder and the voltage generator to control the GIDL voltage to remain at the negative bias voltage and then increase to a second voltage level.

16. The non-volatile memory device of claim 15, wherein the control logic circuit is configured to control, based on the erase operation on the block being performed, the row decoder and the voltage generator to control the GIDL line to remain at the negative bias voltage, and to control the GIDL line to be electrically floating.

17. The non-volatile memory device of claim 16, wherein the control logic circuit is configured to control, based on the erase operation on the block being performed and a difference between the erase voltage and the GIDL voltage being at a predetermined detect voltage level, the row decoder and the voltage generator to control the GIDL line to be electrically floating.

18. The non-volatile memory device of claim 15, wherein the control logic circuit is configured to control, based on the erase operation on the block being performed, the row decoder and the voltage generator to control a second GIDL line connected with a second block to be electrically floating, the second block being not selected by the erase operation.

19. The non-volatile memory device of claim 15, wherein the control logic circuit is configured to control, based on the erase voltage being at a predetermined target voltage level, the row decoder and the voltage generator to control the erase voltage to remain constant.

20. A non-volatile memory device, comprising:
a memory cell array comprising a plurality of memory blocks;
a voltage generator configured to
generate an erase voltage, the erase voltage being provided to at least one of a bit line or a common source line connected with a block among the plurality of memory blocks, the block being targeted for an erase operation, and
generate a negative bias voltage, the negative bias voltage being provided to a gate induced drain leakage (GIDL) line connected with the block; and
a control logic circuit configured to control the voltage generator, and
wherein, based on the erase operation on the block being performed:
the erase voltage is configured to increase, and a GIDL voltage provided to the GIDL line connected with the block is configured to remain at the negative bias voltage during a first time section;
the erase voltage and the GIDL voltage are configured to increase during a second time section after the first time section; and
the erase voltage and the GIDL voltage are configured to remain constant during a third time section after the second time section.
